(19) United States
(12) Patent Application Publication
(10) Pub. No.: US 2020/0144787 A1
(43) Pub. Date: May 7, 2020

(54) OPTICAL MODULE, OPTICAL COMMUNICATION DEVICE, AND MANUFACTURING METHOD THEREOF

(71) Applicant: FUJITSU LIMITED, Kawasaki-shi (JP)

(72) Inventor: NORIO KAINUMA, Nagano (JP)

(73) Assignee: FUJITSU LIMITED, Kawasaki-shi (JP)

(21) Appl. No.: 16/666,600

(22) Filed: Oct. 29, 2019

(30) Foreign Application Priority Data
Nov. 7, 2018 (JP) 2018-209486

(51) Int. Cl. H01S 5/022; H01L 33/62; H04B 10/50

(52) U.S. Cl. CPC H01S 5/02272; H01L 33/62; H04B 10/503; H01L 2924/12042; H01L 2224/29111; H01L 2924/0105; H01L 2224/81801; H01L 2224/29144; H01L 2924/01079

(57) ABSTRACT

An optical module includes a semiconductor chip, a first solder layer formed over the semiconductor chip and having gold and tin as main components, and an optical device provided over the first solder layer, wherein the first solder layer has a portion in which a change in percentage of gold content is different from a change in percentage of gold content in another portion of the first solder layer, in response to a change in position in a facing direction of the semiconductor chip and the optical device.

### CROSS-REFERENCE TO RELATED APPLICATION

This application is based upon and claims the benefit of priority of the prior Japanese Patent Application No. 2018-209486, filed on Nov. 7, 2018, the entire contents of which are incorporated herein by reference.

### FIELD

The embodiment discussed herein is related to an optical module, an optical communication device, and a manufacturing method thereof.

### BACKGROUND

With an increase in amount of data in communication, optical communication devices have been advanced so as to deal with higher frequencies and the larger number of channels. In such a situation, a silicon photonic chip makes it possible to provide an optical communication device with high speed and high density by forming an electric circuit and an optical waveguide over silicon in the same manner as a semiconductor of related art.

On the other hand, it is difficult to enable a silicon photonic chip to emit light due to its material properties, and an optical device that emits light, such as a semiconductor laser, is mounted over a silicon photonic chip by soldering or the like. For soldering the optical device to a semiconductor chip, such as a silicon photonic chip, gold-tin solder containing gold and tin as main components is used, for example.

There has been known a configuration in which an optical semiconductor element is bonded over an optical circuit substrate, a barrier layer made of titanium or the like is formed in an optical semiconductor element mounting portion of the optical circuit substrate, and a gold layer and a tin layer are formed in layers over the barrier layer. There has also been known a configuration in which two or more kinds of solder layers having different melting points and a solder protective layer provided in the uppermost layer of the solder layers are provided in a submount to which a semiconductor element is bonded.

Related art is disclosed in, for example, Japanese Laid-open Patent Publications No. 7-94786 and 2006-278463 and the like.

### SUMMARY

According to an aspect of the embodiments, an optical module includes a semiconductor chip, a first solder layer formed over the semiconductor chip and having gold and tin as main components, and an optical device provided over the first solder layer, wherein the first solder layer has a portion in which a change in percentage of gold content is different from a change in percentage of gold content in another portion of the first solder layer, in response to a change in position in a facing direction of the semiconductor chip and the optical device.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram (part 1) illustrating an example of an optical module according to an embodiment;

FIG. 2 is a diagram (part 2) illustrating an example of the optical module according to the embodiment;

FIG. 3 is a diagram illustrating an example of a solder layer of the optical module according to the embodiment;

FIG. 4 is a diagram (part 1) illustrating an example of a manufacturing method of a solder sheet for forming the solder layer of the optical module according to the embodiment;

FIG. 5 is a diagram (part 2) illustrating an example of the manufacturing method of the solder sheet for forming the solder layer of the optical module according to the embodiment;

FIG. 6 is a diagram (part 3) illustrating an example of the manufacturing method of the solder sheet for forming the solder layer of the optical module according to the embodiment;

FIG. 7 is a diagram (part 1) illustrating an example of a manufacturing method of the optical module according to the embodiment;

FIG. 8 is a diagram (part 2) illustrating an example of the manufacturing method of the optical module according to the embodiment;

FIG. 9 is a diagram (part 3) illustrating an example of the manufacturing method of the optical module according to the embodiment;

FIG. 10 is a diagram (part 4) illustrating an example of the manufacturing method of the optical module according to the embodiment;

FIG. 11 is a cross-sectional view illustrating an example of distribution of gold and tin in the solder sheet during manufacturing of the optical module according to the embodiment;

FIG. 12 is a diagram illustrating an example of a change in distribution of percentage of gold content in a solder sheet of a channel #2 before mounting of an optical device according to the embodiment;

FIG. 13 is a diagram illustrating an example of a change in distribution of percentage of gold content in the solder sheet of the channel #2 immediately after mounting of an optical device of a channel #1 according to the embodiment;

FIG. 14 is a diagram illustrating an example of a change in distribution of percentage of gold content in a solder layer of the channel #2 immediately after mounting of an optical device of the channel #2 according to the embodiment;

FIG. 15 is a diagram illustrating an example of a change in distribution of the percentage of the gold content in the solder layer of the channel #2 immediately after mounting of an optical device of a channel #3 according to the embodiment;

FIG. 16 is a diagram illustrating an example of a change in distribution of the percentage of the gold content in the solder layer of the channel #2 immediately after mounting of an optical device of a channel #4 according to the embodiment;

FIG. 17 is a graph illustrating an example of a relationship between a composition ratio and a melting point in a gold-tin sheet according to the embodiment;

FIG. 18 is a diagram illustrating another example of the solder sheet according to the embodiment;

FIG. 19 is a diagram illustrating an example of a single layer structure of the solder sheet according to the embodiment;

FIG. 20 is a diagram illustrating another example of the single layer structure of the solder sheet according to the embodiment; and

FIG. 21 is a top view illustrating an example of an optical communication device according to the embodiment.

### DESCRIPTION OF EMBODIMENTS

In the related art described above, it is difficult to mount a plurality of optical devices to a semiconductor chip with high accuracy.

For example, when a plurality of optical devices is mounted to a semiconductor chip, a plurality of optical devices is individually bonded to the semiconductor chip in order to position each of the plurality of optical devices with respect to an optical waveguide of the semiconductor chip with high accuracy.

In this case, when gold-tin solder is used for bonding, temperature of the semiconductor chip rises due to heating during soldering of an optical device, thereby increasing a melting point of gold-tin solder for other optical devices being not mounted. This is because gold atoms in gold plating of electrode pads of the semiconductor chip are diffused into the gold-tin solder by heating, for example.

When the melting point of the gold-tin solder for an optical device being not mounted is increased, melting of the gold-tin solder becomes difficult. Therefore, the plurality of optical devices may not be individually bonded to the semiconductor chip, and each of the plurality of optical devices may not be positioned with high accuracy with respect to the optical waveguide of the semiconductor chip.

In view of the above, it is desirable to provide an optical module and an optical communication device capable of improving mounting accuracy of an optical device with respect to a semiconductor chip, and to provide a manufacturing method thereof.

Hereinafter, the embodiment of an optical module, an optical communication device, and a manufacturing method thereof according to the present disclosure will be described in detail with reference to the drawings.

### Embodiment

(Optical Module According to Embodiment)

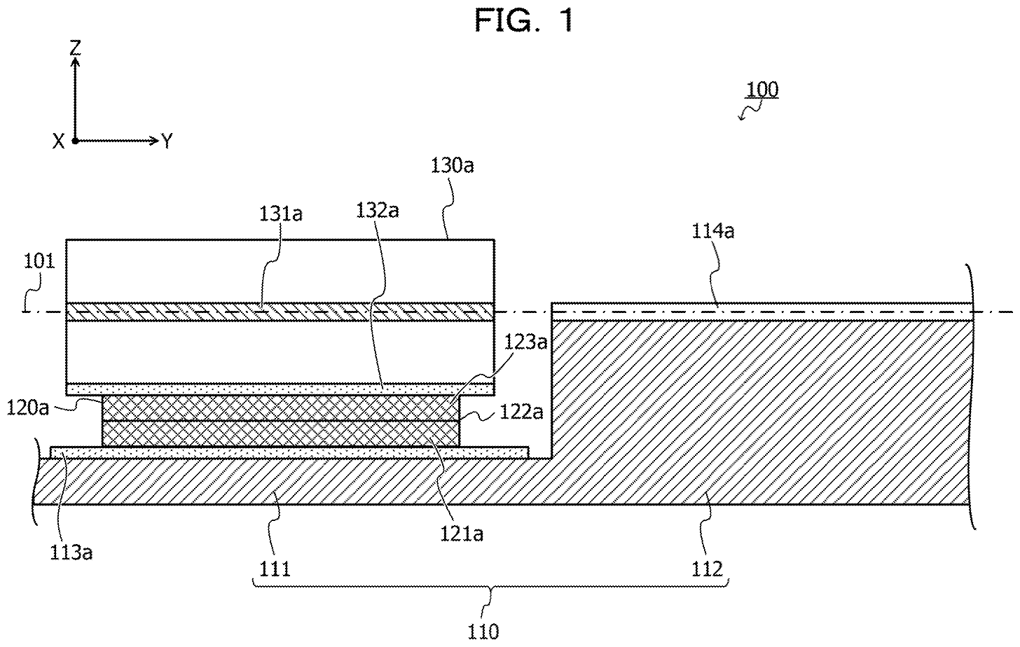

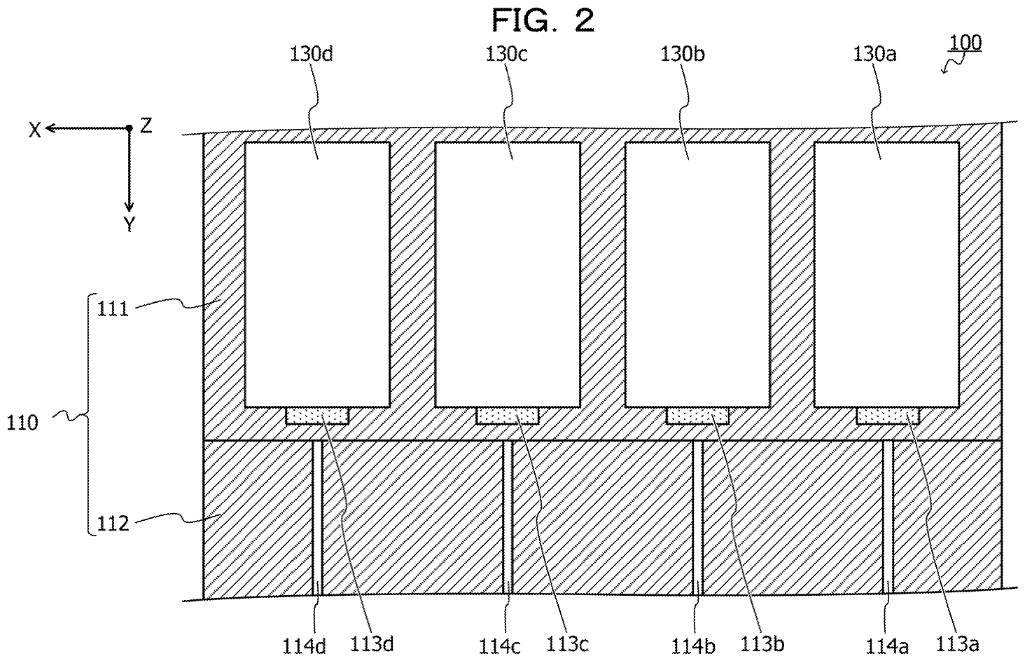

Each of FIG. 1 and FIG. 2 is a diagram illustrating an example of an optical module according to the embodiment. An optical module 100 illustrated in FIG. 1 is a four-channel optical transmission module having channels #1 to #4 as transmission channels. For example, the optical module 100 includes a silicon photonic chip 110 and optical devices 130a to 130d respectively corresponding to the channel #1 to #4.

Each of the optical devices 130a to 130d is a semiconductor laser, such as a laser diode, which oscillates laser light and emits the oscillated laser light. The optical devices 130a to 130d are arranged in a depth direction in FIG. 1 (in a lateral direction in FIG. 2). Each of the optical devices 130a to 130d emits laser light in a direction orthogonal to an arrangement direction of the optical devices 130a to 130d (a right direction in FIG. 1, a downward direction in FIG. 2).

The arrangement direction of the optical devices 130a to 130d (the depth direction in FIG. 1, the lateral direction in FIG. 2) is defined as an X-axis direction, and an emission direction (a lateral direction in FIG. 1, a longitudinal direction in FIG. 2) of the laser light from each of the optical devices 130a to 130d is defined as a Y-axis direction. A direction orthogonal to the X-axis direction and the Y-axis direction (a longitudinal direction in FIG. 1, a depth direction in FIG. 2) is defined as a Z-axis direction. FIG. 1 illustrates a cross section when the optical module 100 is cut by a YZ plane at a position of the optical device 130a. FIG. 2 illustrates an upper surface of the optical module 100 as viewed from the Z-axis direction.

The silicon photonic chip 110 is a semiconductor chip that is provided by forming a fine optical waveguide structure over a silicon substrate by silicon photonics. For example, the silicon photonic chip 110 includes an optical device mounting portion 111 and an optical waveguide forming portion 112.

The optical device mounting portion 111 is a portion in which the optical devices 130a to 130d are mounted in the silicon photonic chip 110. As illustrated in FIG. 1, a height of a front surface of the optical device mounting portion 111 is lower than a height of a front surface of the optical waveguide forming portion 112. The height here is, for example, a position in the Z-axis direction.

At the front surface of the optical device mounting portion 111, electrode pads 113a to 113d that respectively correspond to the channels #1 to #4 and that are arranged in the X-axis direction are formed. Each of the electrode pads 113a to 113d is an electrode pad containing gold (Au). For example, each of the electrode pads 113a to 113d is formed by plating a surface of an electric conductor (for example, copper) other than gold, or the like, with gold. Alternatively, the entirety of the electrode pads 113a to 113d may be formed of gold. In both cases, at least a front surface side of each of the electrode pads 113a to 113d is a gold layer made of gold.

The optical waveguide forming portion 112 is a portion in which optical waveguides 114a to 114d respectively corresponding to the channels #1 to #4 are formed in the silicon photonic chip 110. The optical waveguides 114a to 114d are arranged in the X-axis direction near the front surface of the optical waveguide forming portion 112, and individually propagate light in the Y-axis direction. For example, the optical waveguide 114a propagates light emitted from the optical device 130a. Similarly, the optical waveguides 114b to 114d propagate light emitted from the optical devices 130b to 130d, respectively.

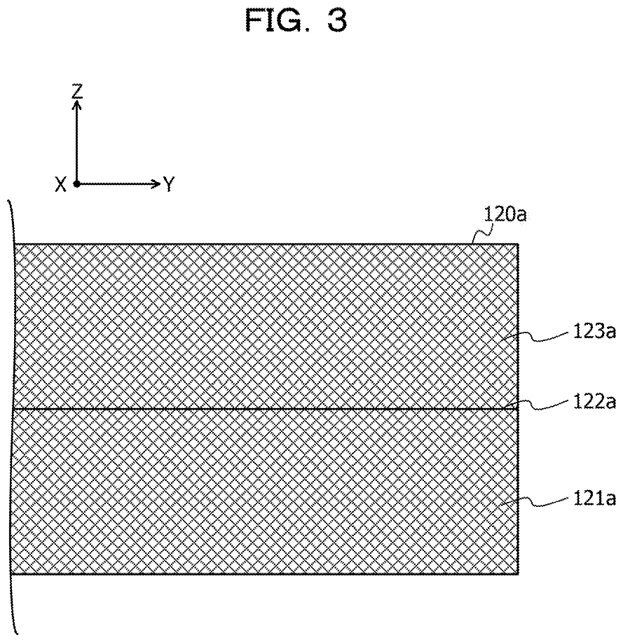

As illustrated in FIG. 1, for example, a solder layer 120a for bonding is provided between the silicon photonic chip 110 and the optical device 130a. The solder layer 120a is formed over the electrode pad 113a, that is, at the front surface side of the electrode pad 113a. The solder layer 120a has a two-layer structure in which a first gold-tin layer 121a and a second gold-tin layer 123a are laminated. A boundary surface 122a is an interface between the first gold-tin layer 121a and the second gold-tin layer 123a. A structure of the solder layer 120a will be described later (see, for example, FIG. 3). The silicon photonic chip 110 and each of the optical devices 130b to 130d are also bonded with each solder layer similar to the solder layer 120a interposed therebetween.

The optical device 130a is disposed over the solder layer 120a, that is, at a front surface side of the solder layer 120a. For example, an electrode pad 132a is formed over a rear surface of the optical device 130a (a surface at a side of the silicon photonic chip 110). The electrode pad 132a is an electrode pad containing gold. For example, the electrode pad 132a is formed by plating a surface of an electric conductor (for example, copper) other than gold, or the like, with gold. Alternatively, the entirety of the electrode pad 132a may be formed of gold. In both cases, at least a front surface side of the electrode pad 132a is a gold layer made of gold.

The optical device 130a is disposed such that the electrode pad 132a is in contact with the front surface (the second gold-tin layer 123a) of the solder layer 120a. As a result, the optical device 130a is fixed to the optical device mounting portion 111 by the solder layer 120a, and is electrically coupled to the optical device mounting portion 111 by the solder layer 120a.

The optical device 130a includes a light emitting portion 131a that oscillates laser light and emits the oscillated laser light in the Y-axis direction. A laser light axis 101 illustrated in FIG. 1 is an optical axis of laser light emitted from the light emitting portion 131a. The optical device 130a is mounted to the optical device mounting portion 111 such that light emitted from the light emitting portion 131a is coupled to the optical waveguide 114a and propagates through the optical waveguide 114a. Similarly, the optical devices 130b to 130d are mounted to the optical device mounting portion 111 such that the emitted light is individually coupled to each of the optical waveguides 114b to 114d and propagates through the optical waveguides 114b to 114d.

(Solder Layer of Optical Module According to Embodiment)

FIG. 3 is a diagram illustrating an example of a solder layer of the optical module according to the embodiment. In FIG. 3, the same portions as those illustrated in FIG. 1 are denoted by the same reference signs and descriptions thereof will be omitted. The solder layer 120a corresponding to the channel #1 will be described, and the respective solder layers corresponding to the channels #2 to #4 are the same as the description of solder layer 120a. As described above, the solder layer 120a illustrated in FIG. 1 includes the first gold-tin layer 121a and the second gold-tin layer 123a.

The first gold-tin layer 121a is formed over the electrode pad 113a of the silicon photonic chip 110 illustrated in FIG. 1, that is, at the front surface side of the electrode pad 113a. The second gold-tin layer 123a is formed over the first gold-tin layer 121a, that is, at a front surface side of the first gold-tin layer 121a.

The first gold-tin layer 121a is an alloy (electric conductor) containing gold and tin (Sn) as main components. The alloy containing gold and tin as main components is, for example, an alloy having total percentage of gold content and tin content that is equal to or more than 95%, that is, an alloy having content percentage of components other than gold and tin that is less than 5%. The second gold-tin layer 123a is an alloy (electric conductor) containing gold and tin as main components.

As described above, both the first gold-tin layer 121a and the second gold-tin layer 123a are alloys containing gold and tin as main components, and there is a certain difference in percentage of gold content between the first gold-tin layer 121a and the second gold-tin layer 123a at the boundary surface 122a. As a result, in the solder layer 120a, each of the first gold-tin layer 121a and the second gold-tin layer 123a is present as a layer. In the example illustrated in FIG. 3, the percentage of the gold content in a portion (boundary surface 122a) of the second gold-tin layer 123a in contact with the first gold-tin layer 121a is higher than the percentage of the gold content in a portion (boundary surface 122a) of the first gold-tin layer 121a in contact with the second gold-tin layer 123a, with a certain difference.

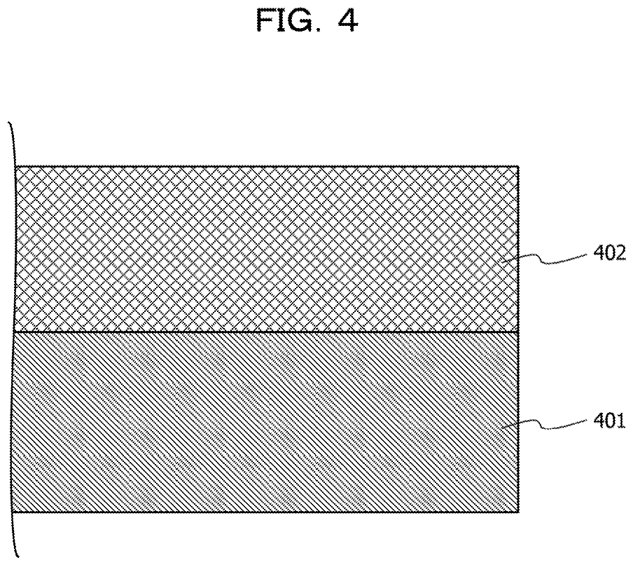

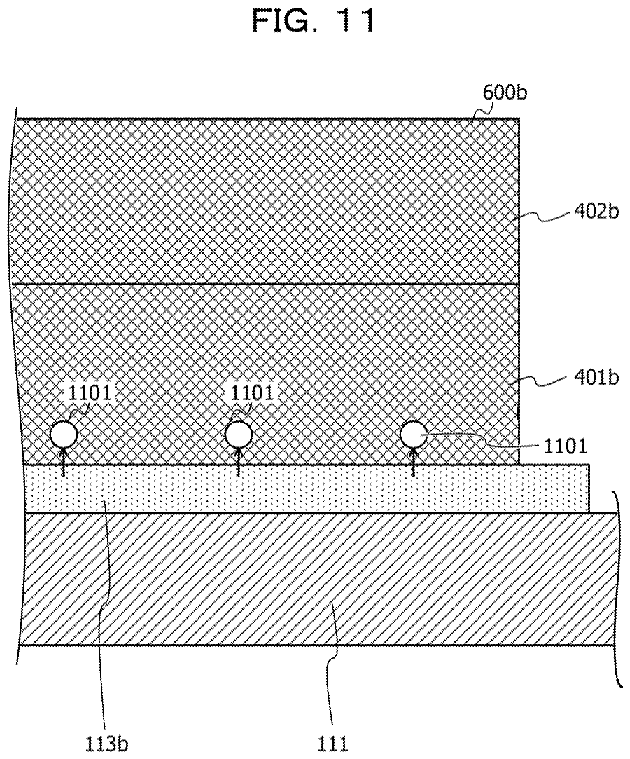

That is, for example, in the solder layer 120a, distribution of percentage of gold content with respect to a position in the Z-axis direction abruptly changes at the boundary surface 122a. As described later, this is because the first gold-tin layer 121a and the second gold-tin layer 123a are made of two gold-tin sheets having different compositions from each other (see, for example, FIG. 4 to FIG. 7). The distribution of the percentage of the gold content in the solder layer 120a will be described later (refer to FIG. 11 to FIG. 16).

In this manner, in the solder layer 120a, the change in percentage of gold content in response to the change in position in the Z-axis direction (a direction in which the silicon photonic chip 110 and the optical device 130a face each other) is different between the first gold-tin layer 121a and the second gold-tin layer 123a. For example, due to gold diffusion to be described later, in the first gold-tin layer 121 a, the closer to the silicon photonic chip 110 the position is, the higher the percentage of the gold content is, and in the second gold-tin layer 123a, the closer to the silicon photonic chip 110 the position is, the lower the percentage of the gold content is. In the solder layer 120a, the change in percentage of gold content in the boundary surface 122a between the first gold-tin layer 121a and the second gold-tin layer 123a is abrupt in response to the change in position in the Z-axis direction. The above-described change in percentage of gold content in the solder layer 120a also has a steep gradient and a gentle gradient.

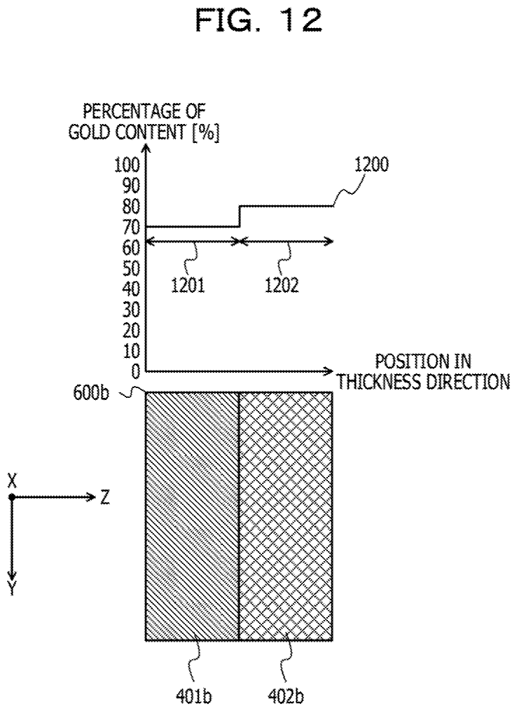

For example, in the solder layer 120a, the percentage of the gold content is gradually increased as the position is closer to the silicon photonic chip 110 or the optical device 130a due to gold diffusion to be described later. The change in percentage of gold content being abrupt or including a steep gradient means that the percentage of the gold content is greatly changed, in comparison with the change in percentage of gold content caused by gold diffusion (for example, see FIG. 12 to FIG. 16).

(Manufacturing Method of Solder Sheet for Forming Solder Layer of Optical Module According to Embodiment)

Each of FIG. 4 to FIG. 6 is a diagram illustrating an example of a manufacturing method of a solder sheet for forming a solder layer of the optical module according to the embodiment. The manufacturing method of the solder sheet for forming the solder layer 120a illustrated in FIG. 3 will be described. First, as illustrated in FIG. 4, a first gold-tin sheet (first gold-tin portion) 401 to be the first gold-tin layer 121a illustrated in FIG. 3 is prepared.

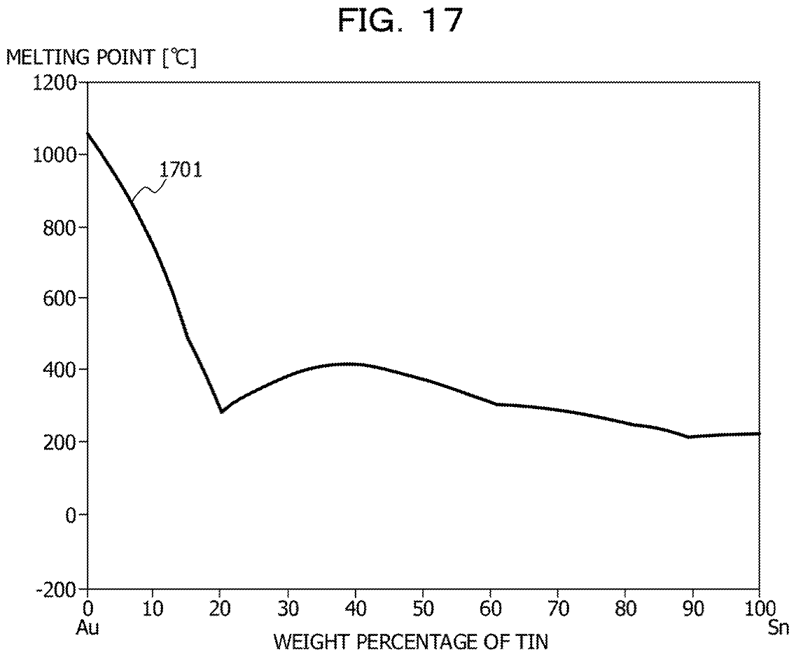

The first gold-tin sheet 401 is sheet-shaped gold-tin solder containing gold and tin as main components. As an example, the first gold-tin sheet 401 is sheet-shaped gold-tin solder (Au70Sn30 solder) having gold content of 70% and tin content of 30%. In this case, a melting point of the first gold-tin sheet 401 is about 380° C. (see, for example, FIG. 17).

Next, as illustrated in FIG. 4, a second gold-tin sheet (second gold-tin portion) 402 to be the second gold-tin layer 123a illustrated in FIG. 3 is disposed over a front surface of the first gold-tin sheet 401. The second gold-tin sheet 402 is a sheet-shaped alloy containing gold and tin as main components. However, the second gold-tin sheet 402 is an alloy whose percentage of gold content is larger than that of the first gold-tin sheet 401, and whose melting point is lower than that of the first gold-tin sheet 401. As an example, the second gold-tin sheet 402 is an alloy (Au80Sn20 solder) having gold content of 80% and tin content of 20%. In this case, the melting point of the second gold-tin sheet 402 is about 280° C. (see, for example, FIG. 17).

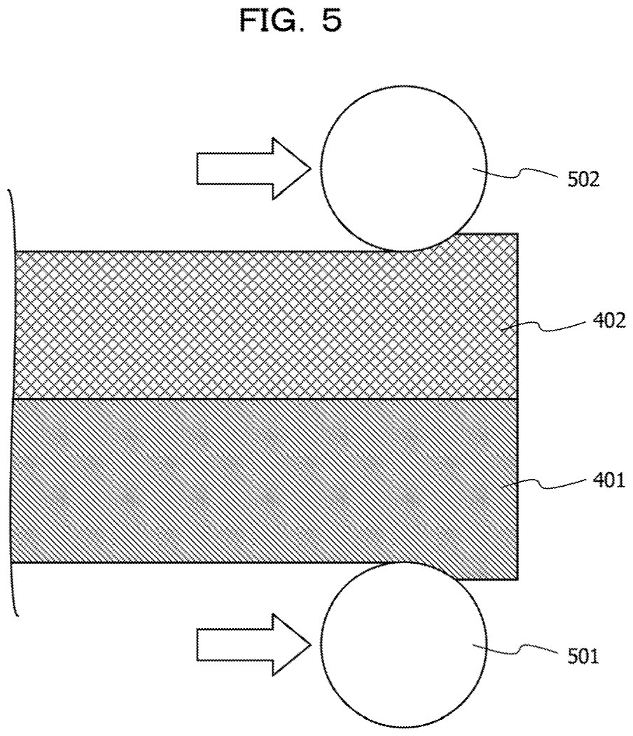

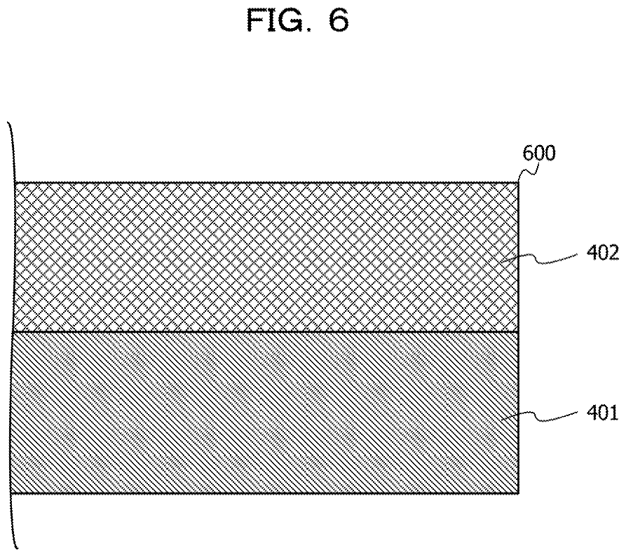

Next, as illustrated in FIG. 5, the first gold-tin sheet 401 and the second gold-tin sheet 402 are rolled by using rollers 501 and 502. The rollers 501 and 502 move in a direction perpendicular to a laminated direction (a lateral direction in FIG. 5) while compressing the first gold-tin sheet 401 and the second gold-tin sheet 402 in the laminated direction (a longitudinal direction in FIG. 5). As a result, as illustrated in FIG. 6, a solder sheet 600 to be the solder layer 120a illustrated in FIG. 3 may be formed.

The compression amounts of the first gold-tin sheet 401 and the second gold-tin sheet 402 by the rollers 501 and 502 are not limited to the example illustrated in FIG. 5. For example, the rollers 501 and 502 may roll the first gold-tin sheet 401 and the second gold-tin sheet 402 such that a total thickness of the first gold-tin sheet 401 and the second gold-tin sheet 402 is approximately half.

The solder sheet 600 is gold-tin solder which is excellent in heat resistance and electric conductivity. For example, it is assumed that the first gold-tin sheet 401 is the Au70Sn30 solder described above, and the second gold-tin sheet 402 is the Au80Sn20 solder described above. In this case, the melting points of the first gold-tin sheet 401 and the second gold-tin sheet 402 are about 380° C. and about 280° C., respectively (see, for example, FIG. 17), which are higher than a melting point (about 220° C.) of silver-tin (SnAg) solder, for example. Therefore, even when bonding is performed with the silver-tin solder or the like in a subsequent process, a bonding portion of the optical device bonded by the gold-tin solder is not affected.

(Manufacturing Method of Optical Module According to Embodiment)

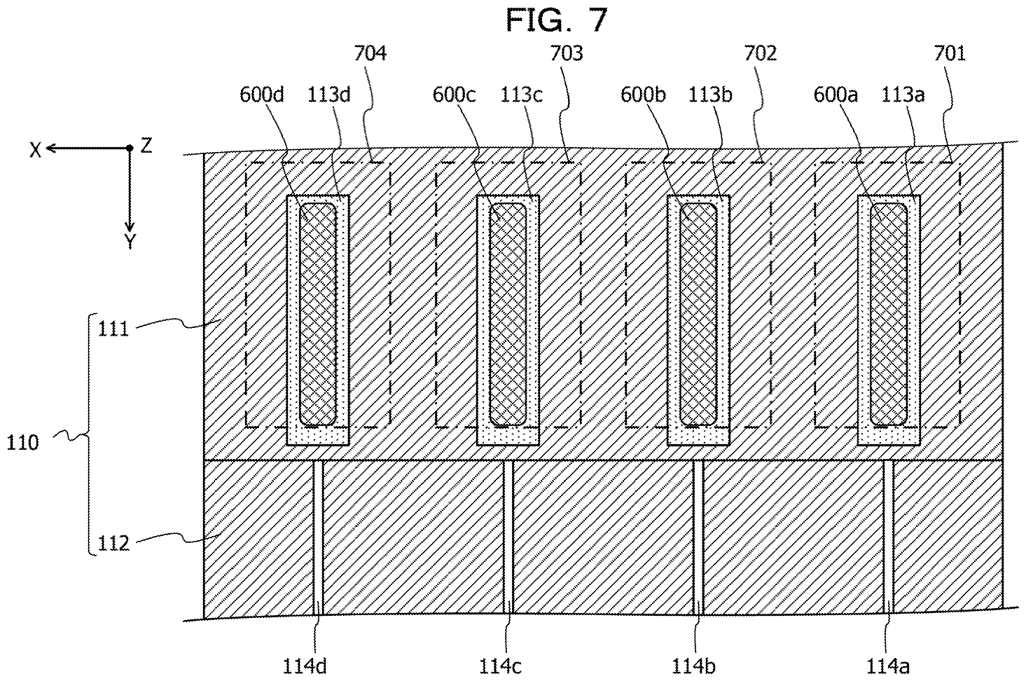

Each of FIG. 7 to FIG. 10 is a diagram illustrating an example of a manufacturing method of the optical module according to the embodiment. FIG. 7 illustrates an upper surface of the silicon photonic chip 110 illustrated in FIG. 1. Optical device mounting planned regions 701 to 704 of the silicon photonic chip 110 illustrated in FIG. 7 are areas for respectively mounting the optical devices 130a to 130d of the channels #1 to #4. The electrode pads 113a to 113d are arranged close to each other, and accordingly, the optical device mounting planned regions 701 to 704 are also close to each other.

First, as illustrated in FIG. 7, solder sheets 600a to 600d are respectively disposed over the electrode pads 113a to 113d. Each of the solder sheets 600a to 600d is a solder sheet similar to the solder sheet 600 illustrated in FIG. 6. The solder sheets 600a to 600d are disposed such that, for example, rear surfaces of the solder sheets 600a to 600d (a lower surface in FIG. 6) are respectively in contact with the electrode pads 113a to 113d.

The solder sheets 600a to 600d may be respectively disposed without being fixed over the electrode pads 113a to 113d, or may be respectively fixed over the electrode pads 113a to 113d by punching, or the like, using a punch.

In this manner, when a plurality of optical devices (for example, the optical devices 130a to 130d) are mounted to the single silicon photonic chip 110, solder (for example, the solder sheets 600a to 600d) corresponding to the respective optical devices is first provided. The optical devices are mounted one by one in this state. This is because it is difficult to simultaneously mount a plurality of optical devices because high accuracy is required for bonding of the optical devices. For example, in the case where each of the optical devices 130a to 130d is a single mode semiconductor laser, accuracy that is equal to or less than ±0.5 [μm] is required for bonding of the optical devices 130a to 130d.

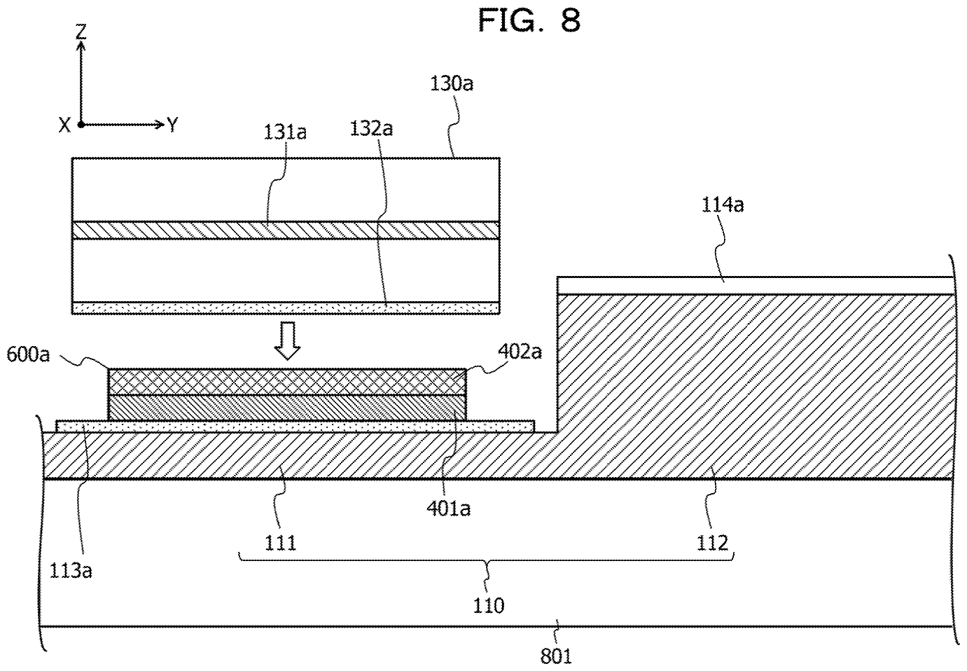

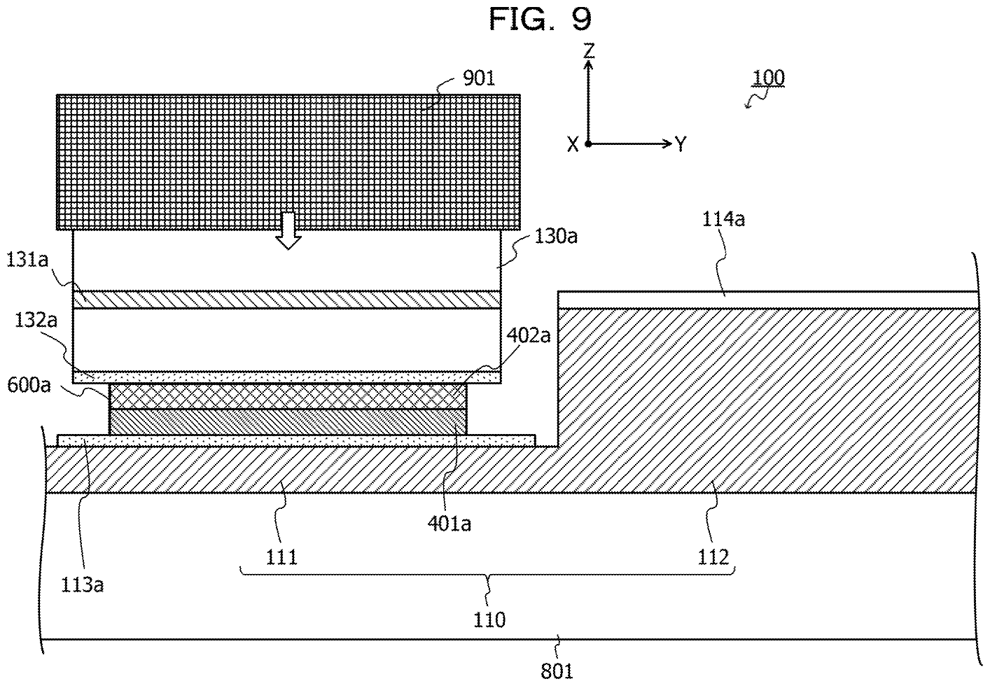

Each of FIG. 8 and FIG. 9 illustrates a cross section by the YZ plane of a portion of the channel #1 in which the optical waveguide 114a and the electrode pad 113a are provided, in the silicon photonic chip 110. A first gold-tin sheet 401a illustrated in FIG. 8 and FIG. 9 is a portion corresponding to the first gold-tin sheet 401 illustrated in FIG. 6 in the solder sheet 600a. A second gold-tin sheet 402a is a portion corresponding to the second gold-tin sheet 402 illustrated in FIG. 6 in the solder sheet 600a.

In the state illustrated in FIG. 7, as illustrated in FIG. 8, the silicon photonic chip 110 is disposed over a bonding stage 801. Alternatively, the silicon photonic chip 110 may be disposed over the bonding stage 801 before the solder sheets 600a to 600d are disposed to the silicon photonic chip 110.

The bonding stage 801 is a stage for pressurizing the silicon photonic chip 110, the solder sheet 600a, and the optical device 130a, together with a bonding tool 901 illustrated in FIG. 9. The bonding stage 801 may have a function of heating the silicon photonic chip 110.

Next, as illustrated in FIG. 8, the optical device 130a is disposed over the solder sheet 600a such that a front surface of the solder sheet 600a disposed over the electrode pad 113a and the electrode pad 132a of the optical device 130a are in contact with each other.

Next, as illustrated in FIG. 9, the bonding tool 901 is disposed over the optical device 130a. The bonding tool 901 performs heating of the optical device 130a and pressurizing of the optical device 130a to the side of the silicon photonic chip 110.

For example, at this time, positional alignment between the light emitting portion 131a of the optical device 130a and the optical waveguide 114a is performed. This alignment may be performed, for example, by putting alignment marks to the optical device 130a and the silicon photonic chip 110, and by moving the optical device 130a such that a positional relationship between the alignment marks becomes a predetermined positional relationship. As a result, as illustrated in FIG. 1, the optical device 130a and the silicon photonic chip 110 are in a positional relationship in which light emitted from the light emitting portion 131a of the optical device 130a is coupled to the optical waveguide 114a.

By heating the optical device 130a by using the bonding tool 901, the solder sheet 600a that is in contact with the optical device 130a is also heated. Temperature of the solder sheet 600a is raised by the heating using the bonding tool 901. For example, when the melting points of the first gold-tin sheet 401 and the second gold-tin sheet 402 are about 380° C. and about 280° C., respectively, as described above, the temperature of the solder sheet 600a is set to about 300° C.

As a result, the first gold-tin sheet 401a and the second gold-tin sheet 402a may be melted. Although 300° C. is lower than the melting point (380° C.) of the first gold-tin sheet 401, temperature of the electrode pad 113a rises due to the heating of the solder sheet 600, and the gold of the electrode pad 113a is diffused into the first gold-tin sheet 401. Therefore, the percentage of the gold content in the first gold-tin sheet 401 is increased, and the melting point of the first gold-tin sheet 401 is close to the melting point (280° C.) of the second gold-tin sheet 402, so that the first gold-tin sheet 401a may be melted even at about 300° C.

Next, the solder sheet 600a is cooled such that the temperature of the solder sheet 600a is lower than the melting points of the first gold-tin sheet 401a and the second gold-tin sheet 402a, thereby solidifying the first gold-tin sheet 401a and the second gold-tin sheet 402a. Thus, the first gold-tin sheet 401a is bonded to the electrode pad 113a, and the second gold-tin sheet 402a is bonded to the electrode pad 132a. The solder sheet 600a may be cooled by, for example, stopping the heating by the bonding tool 901 or weakening the heating by the bonding tool 901.

As the bonding tool 901 heats and cools the solder sheet 600a, as described above, the solder sheet 600a becomes the solder layer 120a illustrated in FIG. 1 and FIG. 3. The first gold-tin sheet 401a becomes the first gold-tin layer 121a illustrated in FIG. 1 and FIG. 3. The second gold-tin sheet 402a becomes the second gold-tin layer 123a illustrated in FIG. 1 and FIG. 3. As a result, as illustrated in FIG. 1, the optical device 130a is bonded to the silicon photonic chip 110 with the solder layer 120a interposed therebetween.

Although a process of heating the solder sheet 600a by the bonding tool 901 has been described, when the bonding stage 801 has a function of heating, the solder sheet 600a may be heated by using the bonding stage 801. Alternatively, heating may be performed by using both the bonding tool 901 and the bonding stage 801. The heating of the solder sheet 600a by the bonding stage 801 is performed by heat of the bonding stage 801 being transmitted to the solder sheet 600a through the silicon photonic chip 110.

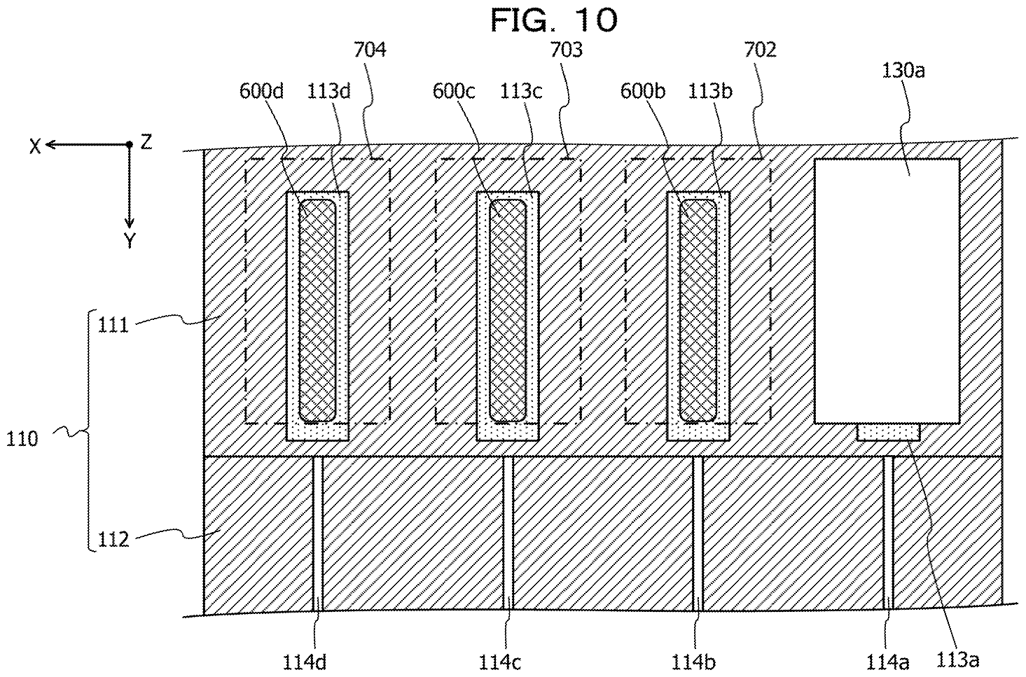

FIG. 10 illustrates the upper surface of the silicon photonic chip 110 after processes illustrated in FIG. 8 and FIG. 9. By the processes illustrated in FIG. 8 and FIG. 9, the optical device 130a of the channel #1 may be mounted in the optical device mounting planned region 701 (see FIG. 7) of the silicon photonic chip 110 as illustrated in FIG. 10.

Next, the optical device 130b of the channel #2 is mounted in the optical device mounting planned region 702 of the silicon photonic chip 110 by the same processes as those illustrated in FIG. 8 and FIG. 9. Next, the optical device 130c of the channel #3 is mounted in the optical device mounting planned region 703 of the silicon photonic chip 110 by the same processes as those illustrated in FIG. 8 and FIG. 9. Next, the optical device 130d of the channel #4 is mounted in the optical device mounting planned region 704 of the silicon photonic chip 110 by the same processes as those illustrated in FIG. 8 and FIG. 9.

Thus, the optical module 100 (see FIG. 1 and FIG. 2) in which the optical devices 130a to 130d of the channels #1 to #4 are mounted to the silicon photonic chip 110 may be manufactured. After mounting the optical devices 130a to 130d to the silicon photonic chip 110, the bonding stage 801 and the bonding tool 901 are removed from the optical module 100.

(Distribution of Gold and Tin in Solder Sheet During Manufacturing of Optical Module According to Embodiment)

FIG. 11 is a cross-sectional view illustrating an example of distribution of gold and tin in the solder sheet during manufacturing of the optical module according to the embodiment. In FIG. 11, the same portions as those illustrated in FIG. 6 and FIG. 7 are denoted by the same reference signs and descriptions thereof will be omitted.

FIG. 11 illustrates a cross section by the YZ plane of a portion of the channel #2 where the electrode pad 113b is provided, in the optical device mounting portion 111 of the silicon photonic chip 110. FIG. 11 illustrates distribution of gold and tin in the solder sheet 600b of the channel #2 immediately after the optical device 130a of the channel #1 is mounted to the silicon photonic chip 110 by heating and cooling the solder sheet 600a described with reference to FIG. 9.

A first gold-tin sheet 401b illustrated in FIG. 11 is a portion corresponding to the first gold-tin sheet 401 illustrated in FIG. 6 in the solder sheet 600b. A second gold-tin sheet 402b illustrated in FIG. 11 is a portion corresponding to the second gold-tin sheet 402 illustrated in FIG. 6 in the solder sheet 600b.

When the solder sheet 600a of the channel #1 described in FIG. 9 is heated, heat of the solder sheet 600a is transmitted to the electrode pad 113b of the channel #2 through the silicon photonic chip 110. In the case of heating by the bonding stage 801 described above, the heat of the bonding stage 801 is transmitted to the electrode pad 113b of the channel #2 through the optical device mounting portion 111 of the silicon photonic chip 110.

Thereby, diffusion of gold atoms 1101 in the gold plating of the electrode pad 113b becomes active, and the gold atoms 1101 move to the first gold-tin sheet 401b in contact with the electrode pad 113b. As a result, as illustrated in FIG. 11, the percentage of the gold content in the first gold-tin sheet 401b becomes high, and average percentage of the gold content in the first gold-tin sheet 401b becomes close to the percentage of the gold content in the second gold-tin sheet 402b. That is, composition of the second gold-tin sheet 402b becomes a composition that is close to composition of the first gold-tin sheet 401b (for example, the above-mentioned Au80Sn20 solder), that is, composition suitable for soldering, for example.

An increase in the percentage of the gold content in the first gold-tin sheet 401b is suppressed until the percentage of the gold content in the first gold-tin sheet 401b (in particular, in a portion in contact with the second gold-tin sheet 402b) becomes equal to the percentage of the gold content in the second gold-tin sheet 402b. By setting original percentage of the gold content in the second gold-tin sheet 402b to be lower than original percentage of the gold content in the first gold-tin sheet 401b as described above, it is possible to suppress an increase in the percentage of the gold content in the second gold-tin sheet 402b due to the diffusion of the gold atoms 1101 in the electrode pad 113b. As a result, it is possible to suppress rise in the melting point of the second gold-tin sheet 402b of the channel #2 due to heating during mounting of the optical device 130a of the channel #1.

Therefore, when the optical device 130b of the channel #2 is mounted to the silicon photonic chip 110 by using the solder sheet 600b, it is possible to avoid that the second gold-tin sheet 402b becomes difficult to be melted by heating. That is, it is possible to avoid that bonding between the solder sheet 600b and the optical device 130b becomes difficult due to melting of the second gold-tin sheet 402b. Therefore, the optical device 130b may be mounted to the silicon photonic chip 110 with high accuracy.

As described with reference to FIG. 11, by lowering percentage of gold content in a lower layer of the solder sheet 600b, even when diffusion of gold from the electrode pad 113b is caused by heating when the optical device 130a is mounted, it is possible to avoid that the optical device 130b becomes difficult to be mounted. The lower layer of the solder sheet 600b is the first gold-tin sheet 401b in the example illustrated in FIG. 11.

By lowering percentage of gold content also in a lower layer of the solder sheet 600c of the channel #3, even when diffusion of gold from the electrode pad 113c is caused by heating when the optical devices 130a and 130b are mounted, it is possible to avoid that the optical device 130c becomes difficult to be mounted. By lowering percentage of gold content also in a lower layer of the solder sheet 600d of the channel #4, even when diffusion of gold from the electrode pad 113d is caused by heating when the optical devices 130a to 130c are mounted, it is possible to avoid that the optical device 130d becomes difficult to be mounted.

As for the channel #1, since the optical device 130a is initially mounted among the optical devices 130a to 130d, the gold of the electrode pad 113a is not diffused by heating when the optical devices of the other channels are mounted. Therefore, the solder sheet 600a is not required to make the percentage of the gold content in the lower layer low. For example, as for the solder sheet 600a, the second gold-tin sheet 402a may have the same composition as the first gold-tin sheet 401a. The solder sheet 600a may be a single gold-tin sheet having the same composition as the first gold-tin sheet 401a and having thickness thicker than those of the first gold-tin sheet 401a and the second gold-tin sheet 402a.

Thus, even when the optical devices 130a to 130d are mounted to the silicon photonic chip 110 one by one, it is possible to avoid that soldering becomes difficult due to an increase in melting point of the solder layer when the second and subsequent optical devices are mounted. Therefore, it becomes possible to mount the optical devices 130a to 130d to the silicon photonic chip 110 one by one, thereby improving mounting accuracy of the optical devices 130a to 130d.

(Change in Distribution of Percentage of Gold Content in Solder Sheet of Channel #2 Before Mounting of Optical Device According to Embodiment)

FIG. 12 is a diagram illustrating an example of a change in distribution of percentage of gold content in a solder sheet of the channel #2 before mounting of the optical device according to the embodiment. Gold content percentage distribution 1200 illustrates distribution of the percentage of the gold content with respect to a position in a thickness direction (Z-axis direction) of the solder sheet 600b, in the solder sheet 600b of the channel #2. A first gold-tin region 1201 is a region corresponding to the first gold-tin sheet 401b in the gold content percentage distribution 1200. A second gold-tin region 1202 is a region corresponding to the second gold-tin sheet 402b in the gold content percentage distribution 1200.

FIG. 12 illustrates the solder sheet 600b and the gold content percentage distribution 1200 thereof when the solder sheet 600b is disposed over the electrode pad 113b of the silicon photonic chip 110, that is, before the optical devices 130a to 130d are mounted, as illustrated in FIG. 7. As illustrated in FIG. 12, at this time, the percentage of the gold content in the first gold-tin sheet 401b (the first gold-tin region 1201) is about 70%, and the percentage of the gold content in the second gold-tin sheet 402b (the second gold-tin region 1202) is about 80%.

(Change in Distribution of Percentage of Gold Content in Solder Sheet of Channel #2 Immediately After Mounting of Optical Device of Channel #1 According to Embodiment)

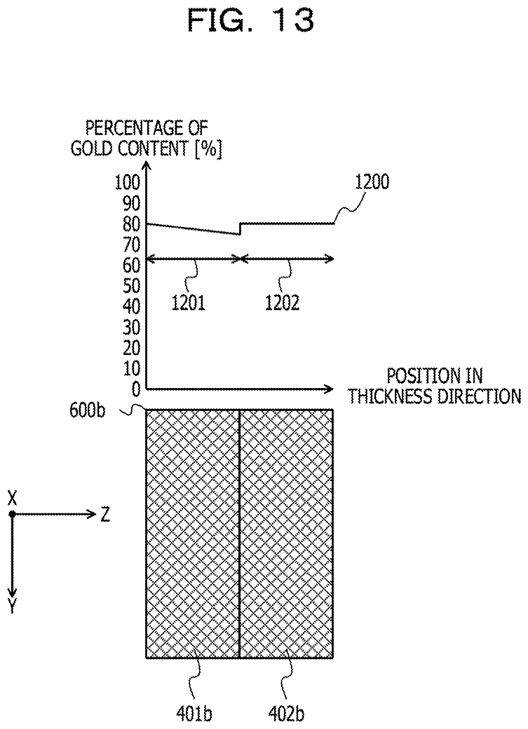

FIG. 13 is a diagram illustrating an example of a change in distribution of percentage of gold content in the solder sheet of the channel #2 immediately after mounting of the optical device of the channel #1 according to the embodiment. After the state illustrated in FIG. 12, when the optical device 130a of the channel #1 is mounted to the silicon photonic chip 110 by heating and cooling of the solder sheet 600a, the solder sheet 600b and the gold content percentage distribution 1200 are as illustrated in FIG. 13. As illustrated in FIG. 13, the percentage of the gold content in the first gold-tin sheet 401b is increased by diffusion of gold from the electrode pad 113b due to heating when the optical device 130a is mounted.

As a result, as described in FIG. 11, average composition of the second gold-tin sheet 402b becomes close to composition of the first gold-tin sheet 401b. Since a portion closer to the electrode pad 113b in the first gold-tin sheet 401b is more likely to be subjected to diffusion by gold from the electrode pad 113b, as illustrated in FIG. 13, the percentage of the gold content becomes larger in the portion closer to the electrode pad 113b in the first gold-tin sheet 401b (a left side in FIG. 13).

(Change in Distribution of Percentage of Gold Content in Solder Layer of Channel #2 Immediately After Mounting of Optical Device of Channel #2 According to Embodiment)

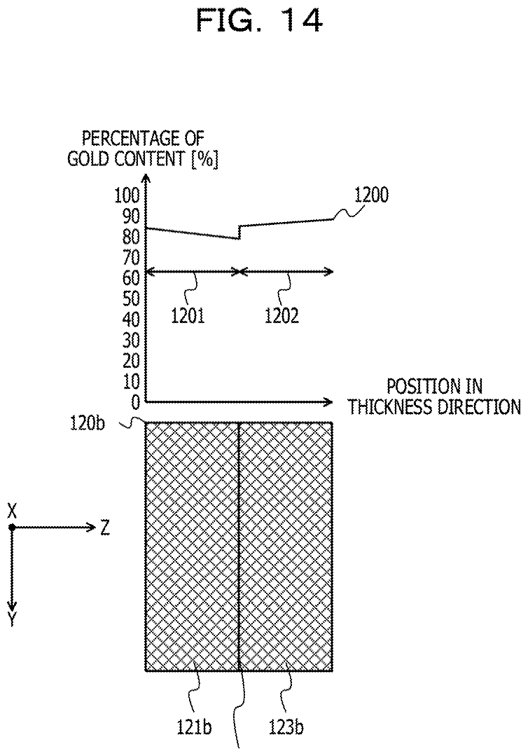

FIG. 14 is a diagram illustrating an example of a change in distribution of the percentage of the gold content in the solder layer of the channel #2 immediately after mounting of the optical device of the channel #2 according to the embodiment. After the state illustrated in FIG. 13, when the optical device 130b of the channel #2 is mounted to the silicon photonic chip 110 by heating and cooling the solder sheet 600b illustrated in FIG. 13, the solder sheet 600b illustrated in FIG. 13 becomes a solder layer 120b.

The solder layer 120b is a solder layer of the channel #2 corresponding to the solder layer 120a, and bonds the silicon photonic chip 110 and the optical device 130b. A first gold-tin layer 121b is a portion corresponding to the first gold-tin layer 121a in the solder layer 120b. A second gold-tin layer 123b is a portion corresponding to the second gold-tin layer 123a in the solder layer 120b. A boundary surface 122b is an interface between the first gold-tin layer 121b and the second gold-tin layer 123b.

The gold content percentage distribution 1200 in each of FIG. 14 to FIG. 16 indicates the distribution of the percentage of the gold content in the solder layer 120b of the channel #2 with response to a position in the thickness direction (Z-axis direction) of the solder layer 120b. In this case, the first gold-tin region 1201 is a region corresponding to the first gold-tin layer 121b of the gold content percentage distribution 1200. The second gold-tin region 1202 is a region corresponding to the second gold-tin layer 123b in the gold content percentage distribution 1200.

As illustrated in FIG. 14, percentage of gold content in the first gold-tin layer 121b is increased by diffusion of gold from the electrode pad 113b (a left side in FIG. 14) of the silicon photonic chip 110 due to heating when the optical device 130b is mounted.

Percentage of gold content in the second gold-tin layer 123b is also increased by diffusion of gold from an electrode pad (a right side in FIG. 14) of the optical device 130b due to the heating when the optical device 130b is mounted. The electrode pad of the optical device 130b is an electrode pad corresponding to the electrode pad 113a of the optical device 130a in the optical device 130b.

A portion closer to the electrode pad of the optical device 130b in the second gold-tin layer 123b is more likely to be subjected to diffusion of gold from the electrode pad of the optical device 130b. Therefore, as illustrated in FIG. 14, percentage of gold content is increased in the portion closer to the electrode pad of the optical device 130b in the second gold-tin layer 123b (the right side in FIG. 14).

(Change in Distribution of Percentage of Gold Content in Solder Layer of Channel #2 Immediately After Mounting of Optical Device of Channel #3 According to Embodiment)

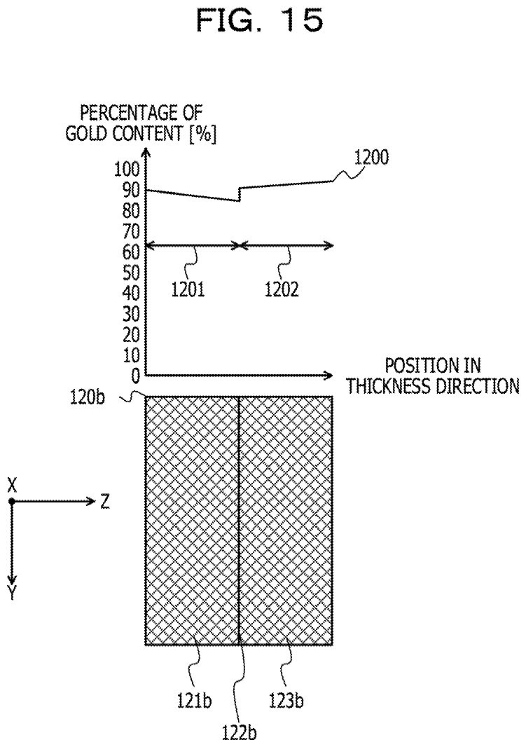

FIG. 15 is a diagram illustrating an example of a change in distribution of the percentage of the gold content in the solder layer of the channel #2 immediately after mounting of an optical device of a channel #3 according to the embodiment. After the state illustrated in FIG. 14, when the optical device 130c of the channel #3 is mounted to the silicon photonic chip 110 by heating and cooling the solder sheet 600c, the gold content percentage distribution 1200 of the solder layer 120b is as illustrated in FIG. 15.

As illustrated in FIG. 15, percentage of gold content in the first gold-tin layer 121b is increased by diffusion of gold from the electrode pad 113b (a left side in FIG. 15) of the silicon photonic chip 110 due to heating when the optical device 130c is mounted. Percentage of gold content in the second gold-tin layer 123b is also increased by diffusion of gold from the electrode pad (a right side in FIG. 15) of the optical device 130b due to heating when the optical device 130c is mounted.

As described above, after mounting of the optical device 130b of the channel #2, the diffusion of gold from the electrode pad of the optical device 130b also occurs in addition to the diffusion of gold from the electrode pad 113b of the silicon photonic chip 110. Therefore, even when the percentage of the gold content in the first gold-tin layer 121b is increased, the percentage of the gold content in the second gold-tin layer 123b is also increased at the same time, so that a state in which the percentage of the gold content in the first gold-tin layer 121b is lower than the percentage of the gold content in the second gold-tin layer 123b is maintained at the boundary surface 122b.

(Change in Distribution of Percentage of Gold Content in Solder Layer of Channel #2 Immediately After Mounting of Optical Device of Channel #4 According to Embodiment)

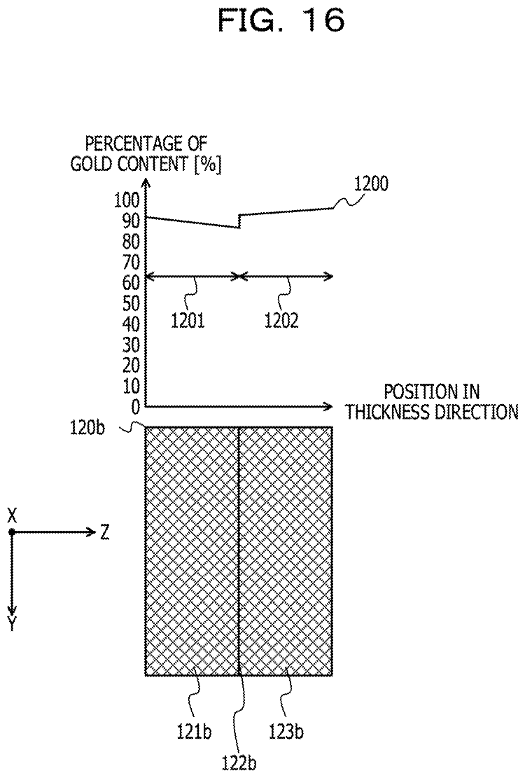

FIG. 16 is a diagram illustrating an example of a change in distribution of the percentage of the gold content in the solder layer of the channel #2 immediately after mounting of an optical device of a channel #4 according to the embodiment. After the state illustrated in FIG. 15, when the optical device 130d of the channel #4 is mounted to the silicon photonic chip 110 by heating and cooling the solder sheet 600d, the gold content percentage distribution 1200 of the solder layer 120b is as illustrated in FIG. 16.

As illustrated in FIG. 16, percentage of gold content in the first gold-tin layer 121b is increased by diffusion of gold from the electrode pad 113b (a left side in FIG. 16) of the silicon photonic chip 110 due to heating when the optical device 130d is mounted. Percentage of gold content in the second gold-tin layer 123b is also increased by diffusion of gold from the electrode pad (a right side in FIG. 16) of the optical device 130b due to heating when the optical device 130d is mounted.

In this case as well, similarly to the state illustrated in FIG. 15, a state in which the percentage of the gold content in the first gold-tin layer 121b is lower than the percentage of the gold content in the second gold-tin layer 123b is maintained at the boundary surface 122b. That is, the solder layer 120b has a portion (boundary surface 122b) where a change in percentage of gold content is different from that in the other portion of the solder layer 120b in response to a change in position in a facing direction (thickness direction of the solder layer 120b) of the silicon photonic chip 110 and the optical device 130b (the thickness direction of the solder layer 120b). At this time, the percentage of the gold content in each of the first gold-tin layer 121b and the second gold-tin layer 123b is, for example, about 90% to 95%.

As illustrated in FIG. 12 to FIG. 16, the solder layer 120b is formed of the first gold-tin sheet 401 and the second gold-tin sheet 402 having different compositions, and thus the solder layer 120b in the manufactured optical module 100 has the boundary surface 122b where percentage of gold content is abruptly changed. Similarly, each solder layer for bonding the optical device 130c of the channel #3 and the optical device 130d of the channel #4 to the silicon photonic chip 110 also has a boundary surface where percentage of gold content is abruptly changed.

However, for example, the solder layer of the channel #4 is subjected to diffusion of gold from the electrode pad 113d when each of the optical devices 130a to 130c is mounted, and is not subjected to diffusion of gold from the electrode pad of the optical device 130d. For this reason, the solder layer of the channel #4 may not have a boundary surface where percentage of gold content is abruptly changed. Similarly, the solder layer of the channel #3 may not have a boundary surface where percentage of gold content is abruptly changed.

(Relationship Between Composition Ratio and Melting Point in Gold-tin Sheet According to Embodiment)

FIG. 17 is a graph illustrating an example of a relationship between a composition ratio and a melting point in a gold-tin sheet according to the embodiment. A relationship between a composition ratio and a melting point in the second gold-tin sheet 402 of the solder sheet 600 illustrated in FIG. 6 will be described as an example, and a relationship between a composition ratio and a melting point of the first gold-tin sheet 401 of the solder sheet 600 is also similar to the above relationship. It is assumed that the second gold-tin sheet 402 is formed only of gold and tin.

In FIG. 17, a horizontal axis (Au, Sn) represents tin content in the second gold-tin sheet 402 by weight percentage, and a vertical axis represents the melting point [° C.] of the second gold-tin sheet 402. Melting point characteristics 1701 indicates characteristics of the melting point of the second gold-tin sheet 402 with respect to the percentage of the tin content in the second gold-tin sheet 402.

As illustrated in the melting point characteristics 1701, when the second gold-tin sheet 402 has a composition having gold content of 80% and tin content of 20%, the melting point is lowered to about 280° C., but when the percentage of the gold content is increased from the composition (eutectic point), the melting point becomes abruptly high. When the percentage of the gold content in the second gold-tin sheet 402 is increased by the diffusion of gold described above, melting of the second gold-tin sheet 402 becomes difficult, and bonding of the optical device by the second gold-tin sheet 402 becomes difficult.

On the other hand, as described above, when the optical module 100 is manufactured, the first gold-tin sheet 401 having percentage of gold content lower than that of the second gold-tin sheet 402 is provided as a lower layer of the second gold-tin sheet 402. The first gold-tin sheet 401 may be, for example, an alloy (Au70Sn30 solder) having gold content of 70% and tin content of 30%, as described above. Thus, it is possible to suppress an increase in the percentage of the gold content in the first gold-tin sheet 401 due to diffusion of gold. Therefore, it is possible to avoid that bonding by the first gold-tin sheet 401 becomes difficult to be performed.

The melting point of the first gold-tin sheet 401 is higher than that of the second gold-tin sheet 402. For example, as described above, the first gold-tin sheet 401 is made of Au70Sn30 solder, and the second gold-tin sheet 402 is made of Au80Sn20 solder. In this case, as illustrated in the melting point characteristics 1701, the melting point of the first gold-tin sheet 401 is about 380° C., which is higher than the melting point (about 380° C.) of the second gold-tin sheet 402.

Thus, it is possible to avoid that, before soldering of the solder sheet 600, the first gold-tin sheet 401 is melted during soldering of the adjacent channel, and tin of the second gold-tin sheet 402 is melted into the first gold-tin sheet 401. Therefore, it is possible to avoid that the percentage of tin content in the second gold-tin sheet 402 is reduced, the melting point of the second gold-tin sheet 402 is increased, and the soldering of the optical device by the second gold-tin sheet 402 becomes difficult.

(Another Example of Solder Sheet According to Embodiment)

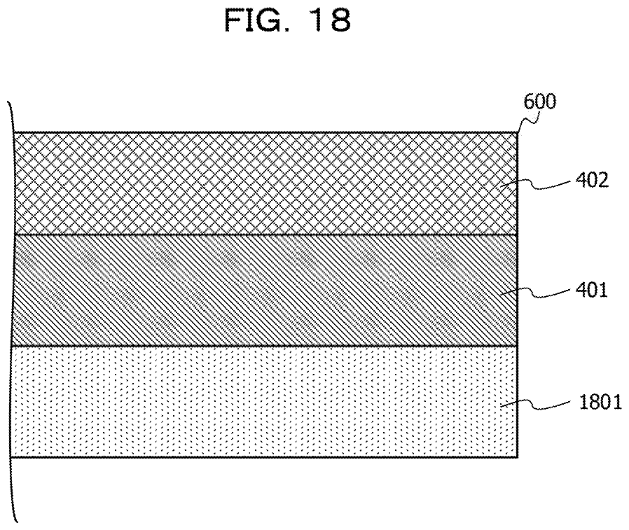

FIG. 18 is a diagram illustrating another example of the solder sheet according to the embodiment. Although the configuration has been described in which the solder sheet 600 (solder layer) has a two-layer structure of the first gold-tin sheet 401 and the second gold-tin sheet 402, the solder sheet 600 may have a structure having three or more layers.

For example, as illustrated in FIG. 18, the solder sheet 600 may further include a third gold-tin sheet 1801 at a rear surface side of the first gold-tin sheet 401 in the configuration illustrated in FIG. 6. The third gold-tin sheet 1801 is a sheet-shaped alloy containing gold and tin as main components, similarly to the first gold-tin sheet 401 and the second gold-tin sheet 402. In this case, the first gold-tin sheet 401 and the second gold-tin sheet 402 are formed to be thinner than those illustrated in FIG. 6.

As an example, the third gold-tin sheet 1801 may be gold and tin (Au70Sn30 solder) having gold content of 70%. The first gold-tin sheet 401 may be gold and tin (Au75Sn25 solder) having gold content of 75%. The second gold-tin sheet 402 may be gold and tin (Au80Sn20 solder) having gold content of 80%. In this manner, each gold-tin sheet is arranged such that percentage of gold content is lower as the gold-tin sheet is closer to the electrode pad (for example, electrode pad 113a) of the silicon photonic chip 110.

With this manner, an increase in the percentage of the gold content in the second gold-tin sheet 402 due to diffusion of gold from the electrode pad of the silicon photonic chip 110 may be suppressed by the first gold-tin sheet 401. The increase in the percentage of the gold content in the first gold-tin sheet 401 due to the diffusion of gold from the electrode pad of the silicon photonic chip 110 may also be suppressed by the third gold-tin sheet 1801.

Therefore, distribution of percentage of the gold content in the solder sheet 600 after heating when the optical device of the adjacent channel is mounted is made more uniform (closer to 80%), and soldering by using the solder sheet 600 of the own channel may be made easier.

However, the percentage of the gold content in the third gold-tin sheet 1801 may be equal to or higher than the percentage of the gold content in the first gold-tin sheet 401. That is, when the percentage of the gold content in the first gold-tin sheet 401 immediately below the second gold-tin sheet 402 is lower than the percentage of the gold content in the second gold-tin sheet 402, it is possible to suppress the increase in the gold content in the second gold-tin sheet 402 due to the diffusion of gold described above. Therefore, it is possible to suppress that soldering of the optical device becomes difficult due to melting of the second gold-tin sheet 402.

In FIG. 18, a configuration in which the solder sheet 600 has the three-layer structure has been described, but a configuration in which the solder sheet 600 has a four-layer structure may be formed. In this case, for example, in the solder sheet 600 illustrated in FIG. 18, the solder sheet 600 having four or more layers may be formed by further overlaying a gold-tin sheet at a rear surface side of the third gold-tin sheet 1801.

(Single Layer Structure of Solder Sheet According to Embodiment)

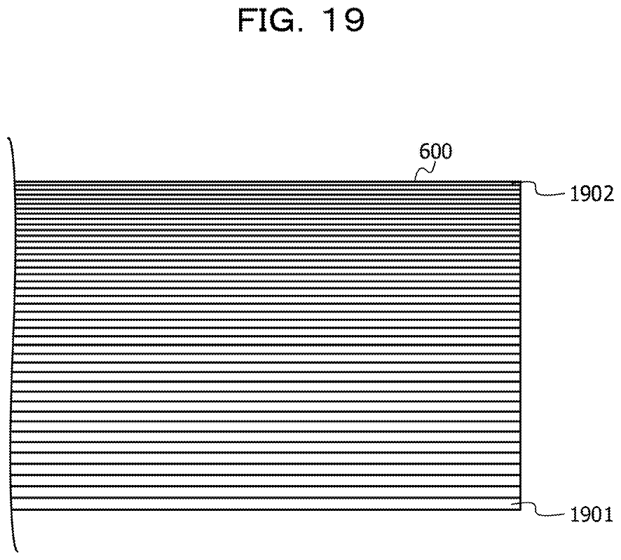

FIG. 19 is a diagram illustrating an example of a single layer structure of the solder sheet according to the embodiment. Although the configuration has been described in which the solder sheet 600 (solder layer) has a multilayer structure in which a plurality of gold-tin sheets is laminated, the solder sheet 600 may have a single layer structure. For example, as illustrated in FIG. 19, a single gold-tin sheet in which main components are gold and tin, and in which percentage of gold content is continuously increased from a rear surface (a lower surface in FIG. 19) to a front surface (an upper surface in FIG. 19) may be used as the solder sheet 600.

As an example, in the solder sheet 600 illustrated in FIG. 19, a first gold-tin portion 1901 at the rear surface is made of Au70Sn30 solder having gold content of 70%, and a second gold-tin portion 1902 at the front surface is made of Au80Sn20 solder having gold content of 80%. In the solder sheet 600 illustrated in FIG. 19, from the first gold-tin portion 1901 to the second gold-tin portion 1902, percentage of the gold content is continuously increased from 70% to 80%.

Accordingly, distribution of the percentage of the gold content in the solder sheet 600 after heating when the optical device of the adjacent channel is mounted is made more uniform (closer to 80%), and soldering by using the solder sheet 600 of the own channel may be made easier.

A melting point of the first gold-tin portion 1901 is higher than a melting point of the second gold-tin portion 1902. As a result, it is possible to avoid that, before soldering of the solder sheet 600, the first gold-tin portion 1901 is melted during soldering of the adjacent channel, and tin of the second gold-tin portion 1902 is melted into the first gold-tin portion 1901. Therefore, it is possible to avoid that the percentage of the tin content in the second gold-tin portion 1902 is reduced, the melting point of the second gold-tin portion 1902 is increased, and the soldering of the optical device by the second gold-tin portion 1902 becomes difficult.

(Another Example of Single Layer Structure of Solder Sheet According to Embodiment)

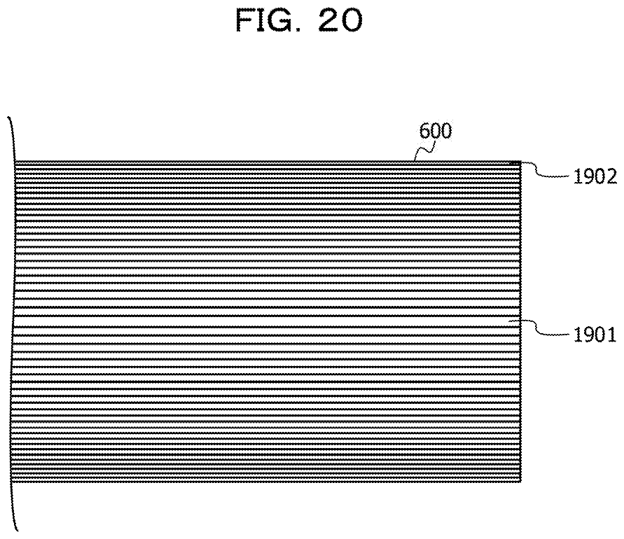

FIG. 20 is a diagram illustrating another example of the single layer structure of the solder sheet according to the embodiment. In FIG. 19, the solder sheet 600 having the single layer structure in which the percentage of the gold content is continuously increased from the rear surface to the front surface has been described, but the solder sheet 600 is not limited to such a structure. For example, as illustrated in FIG. 20, the solder sheet 600 may be a gold-tin sheet in which the percentage of the gold content is continuously changed in a thickness direction (a longitudinal direction in FIG. 20) such that the percentage of the gold content at both ends (the rear surface and the front surface) is high and the percentage of the gold content at the middle is relatively low.

In this case, a middle portion in the thickness direction of the solder sheet 600 becomes the first gold-tin portion 1901 whose percentage of gold content is lower than that of the second gold-tin portion 1902 which is in contact with the optical device. That is, the solder sheet 600 may include the first gold-tin portion 1901 having the lower percentage of the gold content than the second gold-tin portion 1902 at a side (lower side in FIG. 20) of the silicon photonic chip 110 in the second gold-tin portion 1902 that is in contact with the optical device. As a result, it is possible to suppress an increase in the percentage of the gold content in the second gold-tin portion 1902 due to the diffusion of gold described above, thereby suppressing that the soldering of the optical device becomes difficult due to melting of the second gold-tin portion 1902.

As described above, in the optical module according to the embodiment, a solder layer between a semiconductor chip and an optical device includes a first gold-tin layer containing gold and tin as main components, and a second gold-tin layer formed over the first gold-tin layer, having gold and tin as main components, and being in contact with the optical device. Percentage of gold content in a portion of the second gold-tin layer in contact with the first gold-tin layer is higher than percentage of gold content in a portion of the first gold-tin layer in contact with the second gold-tin layer.

Such an optical module is manufactured in the following manner. That is, a solder layer is first disposed over a semiconductor chip. The solder layer includes a first gold-tin portion containing gold and tin as main components, and a second gold-tin portion formed at the opposite side of the semiconductor chip in the first gold-tin portion and containing gold and tin as main components. The first gold-tin portion has higher percentage of gold content than the second gold-tin portion, and has a higher melting point than the second gold-tin portion.

Next, an optical device is disposed over the disposed solder layer, and the solder layer is heated and cooled. Thereby, soldering of the optical device over the semiconductor chip may be performed to manufacture the optical module described above.

In the above manufacturing process, when a plurality of optical devices is soldered one by one in a state where solder layers corresponding to the plurality of optical devices are disposed, by heating during soldering of a certain first optical device, gold is diffused into a solder layer corresponding to another second optical device. This diffusion of gold is caused, for example, by heating of the electrode pad containing gold and formed over the semiconductor chip.

Since the first gold-tin portion having high percentage of gold content is provided under the second gold-tin portion in the solder layer corresponding to the second optical device, it is possible to suppress diffusion of gold into the second gold-tin portion in the solder layer corresponding to the second optical device. Accordingly, it is possible to suppress that the melting point of the second gold-tin portion in the solder layer corresponding to the second optical device is increased, thereby avoiding that soldering of the second optical device to the semiconductor chip becomes difficult.

Since the melting point of the first gold-tin portion of the solder layer corresponding to the second optical device is higher than that of the second gold-tin portion, the first gold-tin portion of the solder layer corresponding to the second optical device may be melted by heating during soldering of the first optical device. Accordingly, it is possible to suppress that the melting point of the second gold-tin portion in the solder layer corresponding to the second optical device is increased, thereby avoiding that soldering of the second optical device to the semiconductor chip becomes difficult.

Therefore, according to the manufacturing process of the embodiment, even when a plurality of optical devices is mounted to the semiconductor chip one by one, it is possible to avoid that soldering becomes difficult due to an increase in melting point of the solder layer when the second and subsequent optical devices are mounted. Therefore, the plurality of optical devices may be mounted to the semiconductor chip one by one, thereby improving mounting accuracy of each optical device.

In the optical module according to the embodiment, since the optical device is mounted to the semiconductor chip with high accuracy as described above, optical coupling loss between the optical waveguide and the optical device formed over the semiconductor chip, for example, is small, so that optical communication with high performance is possible.

(Optical Communication Device According to Embodiment)

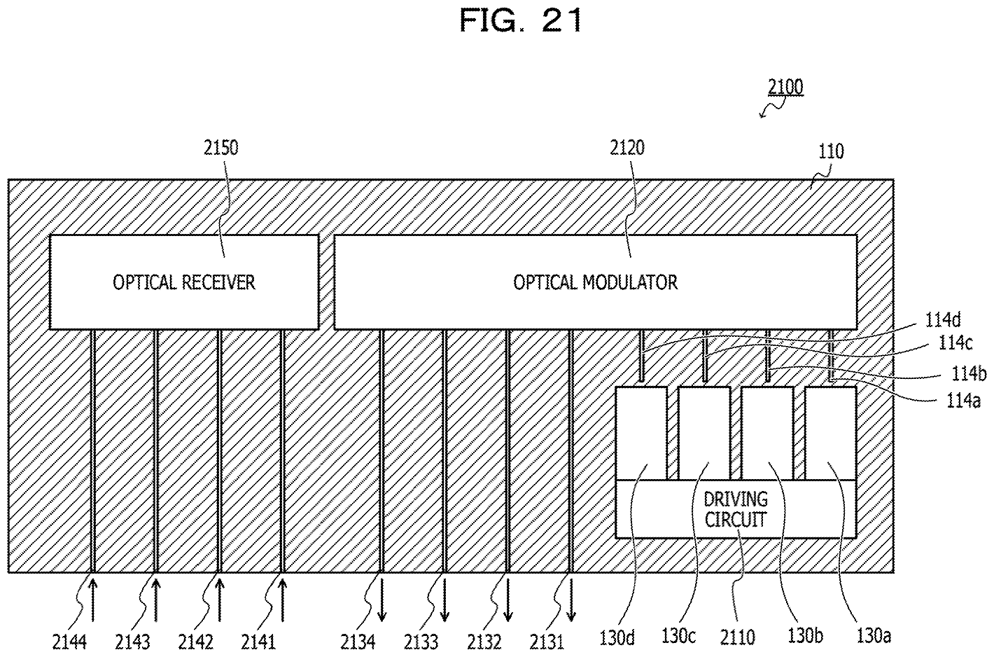

FIG. 21 is a top view illustrating an example of an optical communication device according to the embodiment. An optical communication device 2100 illustrated in FIG. 21 is an optical communication device using the optical module 100 described above. In the example illustrated in FIG. 21, the optical communication device 2100 has channels #1 to #4 as transmission channels, and has channels #5 to #8 as reception channels. For example, the optical communication device 2100 includes the silicon photonic chip 110 and optical devices 130a to 130d.

The silicon photonic chip 110 of the optical communication device 2100 is formed with a driving circuit 2110, the optical waveguides 114a to 114d, an optical modulator 2120, optical waveguides 2131 to 2134, optical waveguides 2141 to 2144, and an optical receiver 2150.

The driving circuit 2110 includes, for example, the electrode pads 113a to 113d illustrated in FIG. 2, and drives the optical devices 130a to 130d by supplying drive current to the optical devices 130a to 130d through the electrode pads 113a to 113d, respectively.

The optical devices 130a to 130d oscillate laser light by the drive current supplied from the driving circuit 2110 through the electrode pads 113a to 113d, respectively, and emit the oscillated laser light to the optical waveguides 114a to 114d, respectively. The optical waveguides 114a to 114d propagate the laser light respectively emitted from the optical devices 130a to 130d and emit the transmitted laser light to the optical modulator 2120.

The optical modulator 2120 modulates the laser light emitted from each of the optical waveguides 114a to 114d, and outputs the optical signal obtained by the modulation to the respective optical waveguides 2131 to 2134. Each of the optical waveguides 2131 to 2134 propagates the laser light emitted from the optical modulator 2120 and sends the laser light to the outside of the silicon photonic chip 110. Thus, the respective optical signals of the channels #1 to #4 are transmitted to a partner device of the optical communication device 2100.

The optical signals of the channels #5 to #8 transmitted from the partner device of the optical communication device 2100 are respectively incident to the optical waveguides 2141 to 2144. Each of the optical waveguides 2141 to 2144 propagates the incident optical signal and emits the optical signal to the optical receiver 2150. The optical receiver 2150 receives the respective optical signals of the channels #1 to #4 emitted from the optical waveguides 2141 to 2144. For example, the optical receiver 2150 includes an optical demodulator for demodulating each of the optical signals of the channels #1 to #4, a light reception portion for receiving each optical signal demodulated by the optical demodulator, a decoding circuit for decoding each signal obtained by the light reception portion, and the like.

The driving circuit 2110, the optical waveguides 114a to 114d, 2131 to 2134, and 2141 to 2144, and the optical receiver 2150 described above may be formed to the silicon photonic chip 110, for example, by silicon photonics. On the other hand, it is difficult to make the silicon photonic chip 110 emit light because of material properties thereof, and as for the optical devices 130a to 130d that emit light, it is difficult to form the silicon photonic chip 110 by silicon photonics. Therefore, the optical devices 130a to 130d are mounted over the silicon photonic chip 110 with solder as described above.

Although the optical communication device 2100 capable of transmitting and receiving an optical signal has been described in FIG. 21, an optical communication device may be applicable in which the optical waveguides 2141 to 2144 and the optical receiver 2150 are omitted from the optical communication device 2100 illustrated in FIG. 21, for example, and that is capable of transmitting an optical signal.

As described above, in the optical communication device according to the embodiment, the optical device may be mounted to the semiconductor chip with high accuracy in the same manner as the optical module according to the embodiment described above. Therefore, for example, optical coupling loss between an optical waveguide formed over a semiconductor chip and an optical device is small, so that optical communication with high performance is possible.

In the above-described optical module 100 and the optical communication device 2100, the configuration in which the semiconductor laser is mounted to the silicon photonic chip 110 as an optical device has been described, but the optical device mounted to the silicon photonic chip 110 is not limited to the semiconductor laser. For example, a semiconductor optical amplifier (SOA) may be mounted to the silicon photonic chip 110 in place of the semiconductor laser. That is, the optical device to be mounted to the silicon photonic chip 110 may be, for example, various optical devices that emit light.

Although the optical module 100 is a four-channel optical transmission module, the number of channels in the optical module 100 may be any number of channels, for example, two or more channels.

As described above, according to the optical module, the optical communication device, and the manufacturing method thereof, it is possible to improve the mounting accuracy of the optical device with respect to the semiconductor chip.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An optical module comprising:
a semiconductor chip;
a first solder layer formed over the semiconductor chip and having gold and tin as main components; and
an optical device provided over the first solder layer, wherein
the first solder layer has a portion in which a change in percentage of gold content is different from a change in percentage of gold content in another portion of the first solder layer, in response to a change in position in a facing direction of the semiconductor chip and the optical device.

2. The optical module according to claim 1, wherein
the first solder layer includes
a first gold-tin layer containing gold and tin as main components, and
a second gold-tin layer formed over the first gold-tin layer and containing gold and tin as main components, and
percentage of gold content in a portion in contact with the first gold-tin layer in the second gold-tin layer is higher than percentage of gold content in a portion in contact with the second gold-tin layer in the first gold-tin layer.

3. The optical module according to claim 1, wherein
an electrode pad containing gold is formed over the semiconductor chip,
the first solder layer is formed over the electrode pad, and
an electrode pad containing gold and being in contact with a front surface of the first solder layer is formed over a surface at a side of the first solder layer of the optical device.

4. The optical module according to claim 3, further comprising:
a second solder layer formed at a position different from the first solder layer over the semiconductor chip; and
an optical device provided over the second solder layer and being different from the optical device.

5. The optical module according to claim 1, wherein
the semiconductor chip is a silicon photonic chip in which an optical waveguide is formed, and
the optical device is a semiconductor laser or a semiconductor optical amplifier configured to emit light to the optical waveguide.

6. The optical module according to claim 2, wherein
a material of the first gold-tin layer is gold-tin solder containing gold and tin as main components, and
a material of the second gold-tin layer is gold-tin solder containing gold and tin as main components, having percentage of gold content higher than percentage of gold content in the gold-tin solder, and having a melting point lower than a melting point of the gold-tin solder.

7. An optical communication device comprising:
a semiconductor chip in which an optical waveguide is formed;
a solder layer formed over the semiconductor chip and containing gold and tin as main components;
an optical device provided over the solder layer and configured to emit light to the optical waveguide; and
a driving circuit configured to drive the optical device, wherein
the first solder layer has a portion in which a change in percentage of gold content is different from a change in percentage of gold content in another portion of the first solder layer, in response to a change in position in a facing direction of the semiconductor chip and the optical device.

8. A manufacturing method comprising:
disposing, over a semiconductor chip, a first solder layer including
a first gold-tin portion containing gold and tin as main components, and
a second gold-tin portion formed at an opposite side of the semiconductor chip in the first gold-tin portion, containing gold and tin as main components, having percentage of gold content higher than percentage of gold content in the first gold-tin portion, and having a melting point lower than a melting point of the first gold-tin portion;
disposing an optical device over the second gold-tin portion of the first solder layer; and
soldering the optical device over the semiconductor chip by heating and cooling the first solder layer.

9. The manufacturing method according to claim 8, wherein
the first solder layer is formed by disposing, over a first gold-tin sheet containing gold and tin as main components, a second gold-tin sheet having percentage of gold content higher than percentage of gold content in the first gold-tin sheet, and having a melting point lower than a melting point of the first gold-tin sheet.

10. The manufacturing method according to claim 8, further comprising:
disposing a second solder layer formed at a position different from the first solder layer and the first solder layer, over the semiconductor chip;
disposing a second optical device different from the optical device (hereinafter referred to as a “first optical device”) over the second solder layer;
soldering the second optical device over the semiconductor chip by heating and cooling the second solder layer;
disposing the first optical device over the first solder layer; and
soldering the first optical device over the semiconductor chip by heating and cooling the first solder layer.
